(19) United States
(12) Patent Application Publication
(10) Pub. No.: US 2007/0222370 A1
(43) Pub. Date: Sep. 27, 2007

(54) Flexible Electroluminescent Devices

(75) Inventors: Furong Zhu, Singapore (SG); Kian Soo Ong, Singapore (SG); Xiaotao Hao, Singapore (SG)

Correspondence Address: MITCHELL P. BROOK;C/O LUCE, FORWARD, HAMILTON & SCRIPPS LLP, 11988 EL CAMINO REAL, SUITE 200, SAN DIEGO, CA, 92130, US

(73) Assignee: AGENCY FOR SCIENCE, TECHNOLOGY AND RESEARCH, CENTROS (SG)

(21) Appl. No.: 10/583,236

(22) PCT Filed: Dec. 30, 2003
(86) PCT No.: PCT/SG03/00296

§ 371 Date: Mar. 6, 2007

(51) Int. Cl. H01J 1/63

(52) U.S. Cl. 313/504

(57) ABSTRACT

An organic light emitting diode (OLED) formed on an opaque flexible substrate is disclosed. The opaque flexible substrate is composed of one of the following: (i) a plastic layer laminated to or coated with a metal layer, (ii) a metal layer sandwiched between two plastic layers, or (iii) a metal foil. When the OLED is formed on a metal surface of the flexible substrate, the metal surface may be coated with an isolation layer. The isolation layer may be a spin-coated polymer layer or a dielectric layer. The metal in the flexible substrate serves as a barrier to minimize the permeation of oxygen and moisture to the OLED. In addition, the OLED is provided with a transparent or semi-transparent upper electrode so that light can emit through the upper electrode.

### FIELD OF THE INVENTION

The present invention generally relates to organic electroluminescent devices, and more particularly to flexible organic light emitting devices (OLEDs).

### BACKGROUND OF THE INVENTION

Organic light emitting devices (OLEDs) have recently attracted attention as display devices that can replace liquid crystal displays (LCDs) because OLEDs can produce high visibility by self-luminescence, thus, they do not require back-lighting, which are necessary for LCDs, and they can be fabricated into lightweight, thin and flexible displays. A typical OLED is constructed by placing an organic light-emitting material between a cathode layer that can inject electrons and an anode layer that can inject holes. When a voltage of proper polarity is applied between the cathode and anode, holes injected from the anode and electrons injected from the cathode combine to release energy as light, thereby producing electroluminescence. Polymeric electroluminescent materials have been used for OLEDs, which devices are referred to as PLEDs.

One conventional structure of OLED is a bottom-emitting structure, which includes a metal or metal alloy cathode and a transparent anode on a transparent substrate, whereby light can be emitted from the bottom of the structure. The OLED may also have a top-emitting structure, which is formed on either an opaque substrate or a transparent substrate. A top-emitting OLED has a relatively transparent top electrode so that light can emit from the side of the top electrode. The top-emitting OLED has two typical structures. When the OLED structure has a transparent anode on top of the organic layers, the structure is referred to as an inverted OLED. The top-emitting OLED can also be made with a transparent cathode on top of the organic layers. The OLED with a transparent anode and a transparent cathode formed on a transparent transparent substrate is referred to as a transparent OLED. The top-emitting OLED structures increase the flexibility of device integration and engineering. Furthermore, the top-emitting OLEDs are desirable for high-resolution displays.

Traditionally, OLEDs have been built on rigid glass substrates. Glass has low permeability to oxygen and water vapors. Over the past few years, ultra thin glass sheets and transparent plastic substrates have been considered as the possible substrate choices for flexible OLEDs and PLEDs. Ultrathin glass sheets, however, are very brittle and OLEDs formed on ultrathin glass sheets have limited potential as flexible OLED displays. To make OLEDs that are lighter, thinner, more rugged and highly flexible, plastic substrates, e.g. polyethylene terephthalate (PET) and polyethylene naphthalate (PEN), have been used for flexible OLEDs. However, these devices have very short lifetimes because plastics exhibit low resistance to water and oxygen. Accordingly, efforts have been made to protect OLEDs formed on plastic substrates from exposure to oxygen and water vapor in order to minimize degradation of the devices.

Various approaches have been proposed for forming barrier protection on plastic substrates. See for example WO 02/065558, WO 02/091064, U.S. Pat. No. 5,757,126, US Pub. No. 2002/0022156. U.S. Pat. No. 5,757,126 discloses a multilayer barrier coating composed of organic and inorganic materials. US Pub. No. 2002/0022156 proposes a multilayer barrier composite formed over a plastic substrate, which composite includes a thin transparent metal oxide or metal nitride and one or more additional layers selected from the group of a thin transparent metallic film, an organic polymer, a thin transparent dielectric, and a thin transparent conductive oxide. WO 02/065558 discloses a transparent polymerized organosilicon protective layer over a transparent polymeric substrate. WO 02/091064 discloses a multilayer barrier that includes organic layers and inorganic layers. These approaches, however, require numerous deposition steps and potentially produce some adverse effects on the optical and mechanical performance of the OLEDs. Thus, these approaches cannot resolve the permeation problem in a cost-effective way.

There remains a need for a flexible OLED that can be easily fabricated in a cost-effective way.

### SUMMARY OF THE INVENTION

The present invention is directed to a flexible organic light emitting diode (OLED), and more specifically, a polymer light emitting diode (PLED), which is formed on an opaque flexible substrate. The opaque flexible substrate is composed of one of the following: (i) a plastic layer laminated to or coated with a metal layer, (ii) a metal layer sandwiched between two plastic layers, or (iii) a metal foil. When the OLED is formed on a metal surface of the flexible substrate, the metal surface may be coated with an isolation layer. The isolation layer may be a spin-coated polymer layer or a dielectric layer. The metal in the flexible substrate serves as a barrier to minimize the permeation of oxygen and moisture to the OLED. In addition, the OLED of the present invention is provided with a transparent or semi-transparent upper electrode so that light can be emitted through the upper electrode. The novel design of the present invention yields an OLED having superior barrier properties and high flexibility, which can be easily fabricated by mass production.

The advantages and novel features of the present invention will become apparent from the following detailed description of the invention when considered in conjunction with the accompanying drawings.

### BRIEF DESCRIPTION OF THE DRAWINGS

FIG. 1 shows a cross-sectional view of a representative OLED formed on a plastic/metal substrate according to the present invention.

FIG. 2 shows a cross-sectional view of the OLED formed on a metal/plastic substrate with an isolation layer according to the present invention.

FIG. 3 shows a cross-sectional view of the OLED formed on a plastic/metal/plastic substrate according to the present invention.

FIG. 4 shows a cross-sectional view of the OLED formed on a metal foil according to the present invention.

FIG. 5 shows an example of an OLED with a transparent multilayer cathode according to the present invention.

### DETAILED DESCRIPTION OF THE PREFERRED EMBODIMENTS

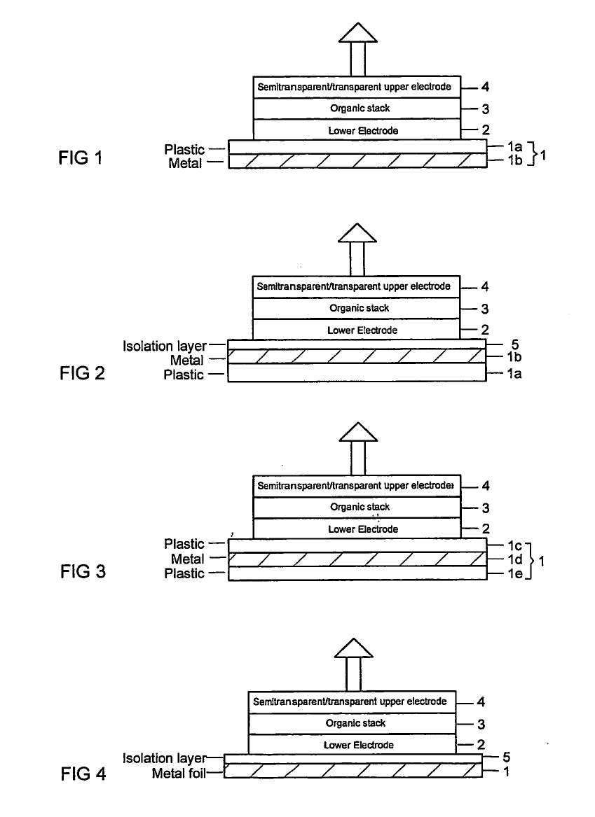

Referring to FIG. 1, the representative OLED of the present invention comprises a flexible opaque substrate 1, a lower electrode 2 on top of the substrate, an organic stack 3 on top of the lower electrode, and a semi-transparent or transparent upper electrode 4 on top of the organic stack. In one embodiment, the flexible opaque substrate 1 is composed of a plastic layer 1a laminated to or coated with a metal layer 1b as shown in FIG. 1. Alternatively, it is also feasible to form the OLED on the metal side of the substrate 1 as shown in FIG. 2. In such a case, it may be desirable to form an isolation layer 5 between the metal layer 1b and the lower electrode 2. In another embodiment shown in FIG. 3, the flexible substrate 1 is composed of a metal layer 1d sandwiched between two plastic layers 1c and 1e. The metallic material used for the substrate 1 includes aluminum and other highly reflective metals. Aluminum is preferred because it is an excellent barrier against water and oxygen. The plastic material used for the flexible substrate 1 includes polyethylene terephthalate (PET), polyethylene naphthalate (PEN), polyether sulfone (PES), and other plastics known in the art to provide the suitable characteristics for flexible OLEDs. The isolation layer 5 may be a spin-coated polymer layer or a dielectric layer, e.g. inorganic oxide or spin-on-glass (SOG). This isolation layer 5 also functions as a planarizing layer.

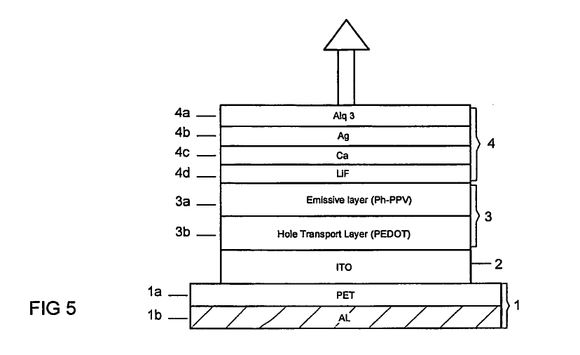

In yet another embodiment shown in FIG. 4, the flexible substrate 1 is a metal foil, which is coated with an isolation layer 5. The metal foil may be made of aluminum, copper or stainless steel. The isolation layer 5 is as described previously for FIG. 2. The metal foil in this case functions as a barrier layer and a mirror-like surface that reflects the emitted light back to the relatively transparent upper electrode 4 to enhance the light output.

The upper electrode 4 may be a cathode or an anode. When the upper electrode 4 is the anode, the lower electrode 2 serves as the cathode, and the OLED is referred to as an inverted OLED. The lower electrode 2 may be transparent or opaque, and reflective or light absorbing. The upper electrode 4 should be semi-transparent or transparent (hereinafter referred to as “relatively transparent”). Suitable materials for the upper electrode 4 and the lower electrode 2 include conductive polymeric materials, conductive organic materials, transparent conductive oxides (TCOs), metals or metal alloys. Examples of TCO include indium-tin-oxide (ITO), zinc-indium-oxide (ZIO), aluminum-doped ZnO, Ga—In—Sn—O (GITO), SnO₂, Zn—In—Sn—O (ZITO), and Ga—In—O (GIO). Suitable metals include gold (Au), silver (Ag), aluminum (Al), iridium (Ir), nickel (Ni) and chromium (Cr). Either of the lower electrode 2 or the upper electrode 4 may be a single layer structure made of one of the materials mentioned above or a multilayer structure made of a combination of these materials. When metals are used as the electrode materials, the interfacial surface of the metal electrode (i.e., the boundary surface between the metal electrode and the organic stack 3) may be modified in order to enhance charge carrier injection in the OLED. TCO (e.g. ITO) has been found to be effective for modifying the metal surface. The materials to be used for modifying the metal surface of the electrode are not limited to TCOs, however, other inorganic materials, as well as organic materials, may also be used for the same purpose. When a metal electrode has been modified, the interfacial modification layer is positioned between the organic stack 3 and the metal electrode.

The relatively transparent upper electrode 4 may be comprised of a single relatively transparent conductive layer, or a multilayer structure containing at least one relatively transparent conductive layer. A multilayer upper electrode may be comprise a relatively transparent conductive layer covered with an index-matching layer in order to enhance the light output. The index-matching layer is made of an organic or inorganic material having a refractive index that is effective for enhancing the light output. Examples of the materials for the index-matching layer are tris-(8-hydroxyquinoline) aluminum (Alq3), N,N′-di(naphthalene-1-yl)-N,N′-diphenylbenzidine (NPB), MgF₂, SiO₂, MgO, ITO, ZnO, TiO₂. In some cases, a TCO layer, e.g. ITO, serve as both a relatively transparent upper electrode and an index-matching layer for enhancing the light output. The index-matching layer also serves as a barrier or an encapsulation layer. The index-matching layer may have a thickness of 1 to 500 nm, depending on the reflective index of the materials being used. The multilayer upper electrode may further include at least one thin, charge carrier injection layer, which is formed between the relatively transparent conductive layer and the organic stack 3. When the multilayer upper electrode is a cathode, the charge carrier injection layer is an electron injection layer. Suitable materials for the electron injection layer include low work function metals such as rare earth metals. When the multilayer upper electrode is an anode, the charge carrier injection layer is a hole injection layer. The hole injection layer may be made of a high work function metal, e.g. Au or Ag, or TCO. Various inorganic materials, organic materials, or combinations of inorganic and organic materials are also feasible as materials for the hole injection layer so long as these materials are effective for hole injection. The charge carrier injection layer may have a thickness of up to 50 nm. The thickness of a single relatively transparent conductive layer may be from 1 to 150 nm. The total thickness of a multilayer electrode structure may be 30 nm or thicker.

It should be understood by one skilled in the art that various materials and multilayer structures are feasible for the upper electrode 4 and the lower electrode 2 so long as they can provide lateral conductivity and interfacial properties required for efficient charge carrier injection.

The organic stack 3 may be a single layer or a multilayer stack comprising a plurality of organic sub-layers adaptable for light emission. The organic materials for the organic stack 3 include electroluminescent and phosphorescent organic materials that are conventional in the art for light emitting devices. More specifically, the organic stack 3 may be made of electroluminescent and/or phosphorescent polymeric materials conventionally used for PLEDs. The organic stack may be a single layer of an emissive material or a bi-layer comprised of a hole transporting layer and a light-emitting layer. Yet another possibility is a three-layer organic stack comprising a hole transporting layer, an electron transporting layer, and an emissive layer between the hole transporting layer and the electron transporting layer. The device having such three-layer organic stack is referred to as a double heterostructure. The hole transporting layer should be next to the anode because the holes are injected from the anode. When an electron transporting layer is used, it should be next to the cathode. The total thickness of the organic stack 3 may range from 50 to 1000 nm.

### AN EXAMPLE OF THE PRESENT INVENTION

One example of a top-emitting PLED according to the present invention is shown in FIG. 5. The flexible substrate 1 is composed of a 125 microns thick PET sheet 1a laminated to a 25 microns thick Al foil 1b. A 120 nm thick transparent ITO anode 2 is formed on the plastic side of the flexible substrate 1. Forming on the ITO anode 2 is a bi-layer organic stack 3 composed of an 80 nm thick emissive layer 3a made of polyphenylene vinylene (Ph-PPV), and a 30 nm thick hole transport layer 3b made of polyethylene dioxythiophene (PEDOT). The relatively transparent cathode 4 is a multilayer structure composed of, in order from the top, a 52 nm thick tris-(8-hydroxyquinoline) aluminum (Alq3) layer 4a, a 15 nm thick semitransparent Ag layer 4b, a 1.0 nm thick calcium (Ca) layer 4c, and a 0.6 nm thick lithium fluoride (LiF) layer 4d. In this case, Alq3 serves as the index-matching layer, Ag serves as the conducting layer for lateral conductivity, and the combination of LiF/Ca serves as the electron injector. The multilayer cathode can be formed by thermal evaporation, thereby avoiding the damaging effect of the sputter deposition process. The Al foil 1b serves as an excellent barrier for the PET substrate, thereby improving the lifetime of the device. This example of the present invention could be considered as a convenient and cost-effective approach for fabricating top-emitting PLEDs.

The present invention offers a flexible OLED on an opaque and flexible substrate that can be bent to a substantial extent without breaking. Thus, the flexible OLED of the present invention has the ability to conform, bend or roll into any shape. This flexibility will enable the fabrication of display devices by continuous roll processing, thereby providing a cost-effective approach for mass production. The flexible substrates disclosed in this invention may also be used for organice photo-detectors, organic thin film transistors, organic photovoltaic cells, organic memories, organic integrated circuits, and other organic or inorganic optoelectronic devices that require flexible substrate with good barrier properties and mechanical flexibility.

The OLED of the present invention has a variety of applications, including mobile phones, PDA and other hand-held devices, computer monitors, digital audio devices, video cameras, lighting devices, decorative devices, and advertising devices.

While the invention has been described with respect to the preferred embodiments, it will be understood by those skilled in the art that modifications may be made in the invention without departing from the spirit and scope of the appended claims.

1. A flexible organic light emitting device comprising:
a flexible substrate;
a lower electrode layer on said flexible substrate;
an upper electrode layer that is at least semi-transparent;
an organic region between said lower electrode layer and said upper electrode layer, in which electroluminescence can take place when a voltage is applied between said lower electrode layer and said upper electrode layer,
wherein said flexible substrate is comprised of one of the following:
(i) a plastic layer laminated to or coated with a metal layer, (ii) a metal layer sandwiched between two plastic layers, and (iii) a metal foil.

2. The flexible organic light emitting device of claim 1, wherein said flexible substrate is comprised of a plastic layer laminated to or coated with an aluminum layer, the plastic layer being positioned between the lower electrode layer and the aluminum layer.

3. The flexible organic light emitting device of claim 1, wherein said flexible substrate is comprised of a steel foil.

4. The flexible organic light emitting device of claim 1 further comprising an isolation layer between said flexible substrate and said lower electrode layer.

5. The flexible organic light emitting device of claim 4, wherein said isolation layer is a spin-coated polymeric layer or a dielectric layer.

6. The flexible organic light emitting device of claim 3 further comprising an isolation layer between said steel foil and said lower electrode layer.

7. The flexible organic light emitting device of claim 1, wherein said upper electrode layer is transparent.

8. The flexible organic light emitting device of claim 1, wherein said upper electrode layer is a semitransparent or transparent anode.

9. The flexible organic light emitting device of claim 1, wherein said upper electrode layer is a semitransparent or transparent cathode.

10. The flexible organic light emitting device of claim 1, wherein said upper electrode layer is a multilayer structure comprising at least one semitransparent or transparent conductive film.

11. The flexible organic light emitting device of claim 10, wherein said multilayer structure comprises an index-matching layer and a charge carrier injection layer.

12. The flexible organic light emitting device of claim 11, wherein said index-matching layer comprises an organic or inorganic material having a refractive index effective for enhancing light output.

13. The flexible organic light emitting device of claim 11, wherein said index-matching layer comprises a combination of organic and inorganic materials that are effective for enhancing light output.

14. The flexible organic light emitting device of claim 11, wherein said multilayer structure is an anode and said charge carrier injection layer is a hole injection layer.

15. The flexible organic light emitting device of claim 14, wherein said hole injection layer comprises a high work function metal or a transparent conductive oxide (TCO).

16. The flexible organic light emitting device of claim 15, wherein said high work function metal is gold or silver.

17. The flexible organic light emitting device of claim 15, wherein said TCO is metal oxide.

18. The flexible organic light emitting device of claim 15, wherein said TCO is selected from the group consisting of indium-tin-oxide (ITO), zinc-indium-oxide, aluminum-doped zinc oxide, Ga—In—Sn—O, SnO₂, Zn—In—Sn—O, and Ga—In—O.

19. The flexible organic light emitting device of claim 14, wherein said hole injection layer comprises an organic material effective for hole injection or a combination of inorganic and organic materials that are effective for hole injection.

20. The flexible organic light emitting device of claim 14, wherein said hole injection layer comprises an inorganic material effective for hole injection or a combination of inorganic and organic materials that are effective for hole injection.

21. The flexible organic light emitting device of claim 11, wherein said multilayer structure is a cathode and said charge carrier injection layer is an electron injection layer.

22. The flexible organic light emitting device of claim 21, wherein said electron injection layer comprises a low work function metal.

23. The flexible organic light emitting device of claim 22, wherein said low work function metal is a rare earth metal.

24. The flexible organic light emitting device of claim 21, wherein said index-matching layer comprises tris-(8-hydroxyquinoline) aluminum (Alq3) or N,N′-di(naphthalene-1-yl)-N,N′-diphenylbenzidine (NPB).

25. The flexible organic light emitting device of claim 21, wherein said cathode comprises a silver layer and said electron injection layer is comprised of a calcium sub-layer over a lithium fluoride sub-layer, the silver layer being formed over the calcium layer.

26. The flexible organic light emitting device of claim 1, wherein at least one of the lower electrode layer and the upper electrode layer is modified to enhance charge carrier injection.

27. The flexible organic light emitting device of claim 1, wherein said organic region comprises (i) a hole transporting layer and (ii) an emissive layer or an electron transporting layer.

28. The flexible organic light emitting device of claim 1, wherein said organic region comprises (i) a hole transporting layer, (ii) an emissive layer, and (iii) an electron transporting layer.
